(19) United States
(12) Patent Application Publication
(10) Pub. No.: US 2026/0053026 A1
(43) Pub. Date: Feb. 19, 2026

(54) PACKAGE SUBSTRATE STRUCTURE AND SEMICONDUCTOR PACKAGE INCLUDING THE SAME

(71) Applicant: SAMSUNG ELECTRONICS CO., LTD., Suwon-si (KR)

(72) Inventors: Jinhee HONG, Suwon-si (KR); Jitaek OH, Suwon-si (KR)

(73) Assignee: SAMSUNG ELECTRONICS CO., LTD., Suwon-si (KR)

(21) Appl. No.: 19/255,062

(22) Filed: Jun. 30, 2025

(30) Foreign Application Priority Data
Aug. 19, 2024 (KR) 10-2024-0110188

(51) Int. Cl. H01L 23/538; H01L 23/00

(52) U.S. Cl. CPC H01L 23/5386; H01L 23/5383; H01L 24/06; H01L 24/48; H01L 2224/06135; H01L 2224/48227

(57) ABSTRACT

A package substrate structure includes a package substrate, first and second substrate pads, and first and second wiring structures. The package substrate has first and second surfaces opposite to each other in a vertical direction. The first and second substrate pads are at the same level as each other in the package substrate, and adjacent to the first surface of the package substrate. The first wiring structure is in the package substrate. At least a portion of the first wiring structure is at the same level as and contacts the first substrate pad. The second wiring structure is in the package substrate. At least a portion of the second wiring structure is at the same level as and contacts the second substrate pad. The second wiring structure has an extension length greater than an extension length of the first wiring and a width smaller than a width of the first wiring.

### CROSS-REFERENCE TO RELATED APPLICATION

This application claims priority under 35 U.S. C. § 119 to Korean Patent Application No. 10-2024-0110188, filed on Aug. 19, 2024 in the Korean Intellectual Property Office (KIPO), the contents of which are herein incorporated by reference in their entirety.

### BACKGROUND

### 1. Field

Example embodiments relate to a package substrate structure and a semiconductor package including the same.

### 2. Description of the Related Art

In a multi-chip package including a plurality of semiconductor chips stacked on a package substrate, chip pads on each of the semiconductor chips and substrate pads on the package substrate may be electrically connected to each other by bonding wires, and the substrate pads may be electrically connected to an outer conductive connection member through a wiring structure in the package substrate. Thus, electrical characteristics of the wiring structure for transferring electrical signals are important.

### SUMMARY

Example embodiments provide a package substrate structure having enhanced electrical characteristics.

Example embodiments provide a semiconductor package having enhanced electrical characteristics.

According to example embodiments, there is provided a package substrate structure. The package substrate structure may include a package substrate, first and second substrate pads, a first wiring structure and a second wiring structure. The package substrate may have first and second surfaces opposite to each other in a vertical direction. The first and second substrate pads may be disposed at the same level as each other in the package substrate, and may be adjacent to the first surface of the package substrate. The first wiring structure may be disposed in the package substrate. At least a portion of the first wiring structure may be at the same level as the first substrate pad, and may contact the first substrate pad. The second wiring structure may be disposed in the package substrate. At least a portion of the second wiring structure may be at the same level as the second substrate pad, and may contact the second substrate pad. The second wiring structure may have an extension length greater than an extension length of the first wiring and a width smaller than a width of the first wiring.

According to example embodiments, there is provided a semiconductor package. The semiconductor package may include a package substrate structure, a first semiconductor chip, a first bonding wire and a second bonding wire. The package substrate structure may include a package substrate, first and second substrate pads, a first wiring structure and a second wiring structure. The package substrate may have first and second surfaces opposite to each other in a vertical direction. The first and second substrate pads may be disposed at the same level as each other in the package substrate, and may be adjacent to the first surface of the package substrate. The first wiring structure may be disposed in the package substrate. At least a portion of the first wiring structure may be at the same level as the first substrate pad, and may contact the first substrate pad. The second wiring structure may be disposed in the package substrate. At least a portion of the second wiring structure may be at the same level as the second substrate pad, and may contact the second substrate pad. The second wiring structure may have an extension length greater than an extension length of the first wiring and a width smaller than a width of the first wiring. The first semiconductor chip may be disposed on the package substrate structure, and may include first and second chip pads at an upper portion thereof. The first bonding wire may contact the first chip pad and the first substrate pad. The second bonding wire may contact the second chip pad and the second substrate pad.

According to example embodiments, there is provided a semiconductor package. The semiconductor package may include a package substrate structure, first and second semiconductor chips, a first bonding wire, a second bonding wire, and first and second conductive connection members. The package substrate structure may include a package substrate, first and second substrate pads, a first wiring structure, a second wiring structure, and third and fourth substrate pads. The package substrate may have first and second surfaces opposite to each other in a vertical direction. The first and second substrate pads may be disposed at the same level as each other in the package substrate, and may be adjacent to the first surface of the package substrate. The first wiring structure may be disposed in the package substrate. At least a portion of the first wiring structure may be at the same level as the first substrate pad, and may contact the first substrate pad. The second wiring structure may be disposed in the package substrate. At least a portion of the second wiring structure may be at the same level as the second substrate pad, and may contact the second substrate pad. The second wiring structure may have an extension length greater than an extension length of the first wiring and a width smaller than a width of the first wiring. The third and fourth substrate pads may be disposed at the same level as each other in the package substrate, and may be adjacent to the second surface of the package substrate. The third and fourth substrate pads may be electrically connected to the first and second wiring structures, respectively. The first and second semiconductor chips may be spaced apart from each other on the package substrate structure in a first direction parallel to an upper surface of the package substrate. The first and second semiconductor chips may include first and second chip pads, respectively, at upper portions thereof. The first bonding wire may contact the first chip pad and the first substrate pad. The second bonding wire may contact the second chip pad and the second substrate pad. The first and second conductive connection members may be disposed on a lower surface of the package substrate structure, and may contact the third and fourth substrate pads, respectively.

The wirings in the package substrate structure in accordance with example embodiments may have reduced parasitic capacitance and crosstalk, and thus the semiconductor package including the package substrate structure may have enhanced electrical characteristics.

### BRIEF DESCRIPTION OF THE DRAWINGS

FIG. 1 is a plan view illustrating a semiconductor package in accordance with example embodiments.

FIG. 2 is an enlarged plan view of a region X of FIG. 1.

FIG. 3 is a plan view illustrating widths of first and second wirings and distances between the first wirings and between the second wirings.

FIG. 4 is a cross-sectional view taken along line A-A′ of FIG. 1.

FIG. 5 is a cross-sectional view taken along line B-B′ of FIG. 1.

FIG. 6 is a plan view illustrating widths and distances of the first and second wirings.

### DETAILED DESCRIPTION OF EXAMPLE EMBODIMENTS

Hereinafter, example embodiments will be explained in detail with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Hereinafter, two directions that are perpendicular to each other among horizontal directions, which are parallel to an upper surface of a substrate or a package substrate, may be referred to as first and second directions D1 and D2, respectively, and a vertical direction that are perpendicular to the upper surface of the substrate or the package substrate may be referred to as a third direction D3. A direction having an acute angle with respect to the first and second directions D1 and D2 among the horizontal directions may be referred to as a fourth direction D4. Each of the first to fourth directions D1, D2, D3 and D4 may include not only a direction shown in the drawings but also a direction opposite thereto.

An extension direction of a structure may refer to a direction in which the structure has a relatively longer length, and a width of the structure may refer to a length in a direction perpendicular to the extension direction.

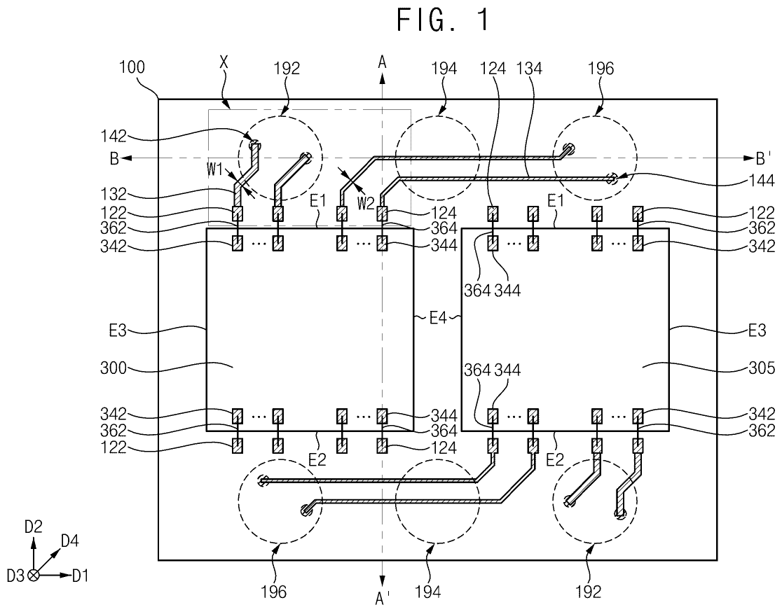

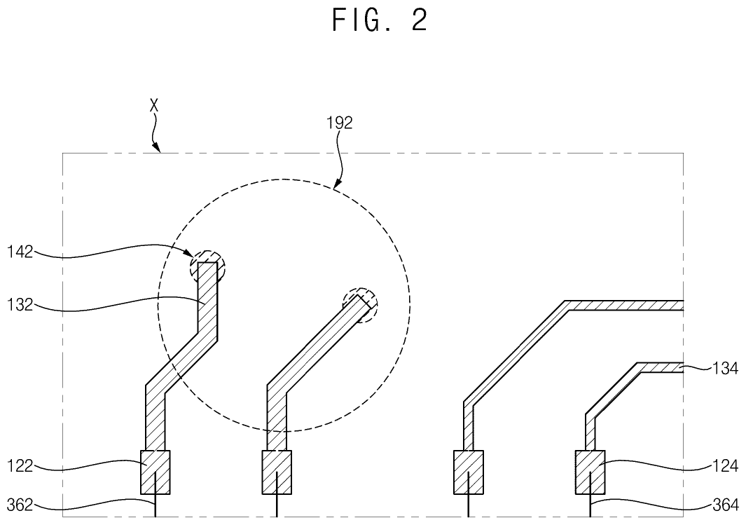

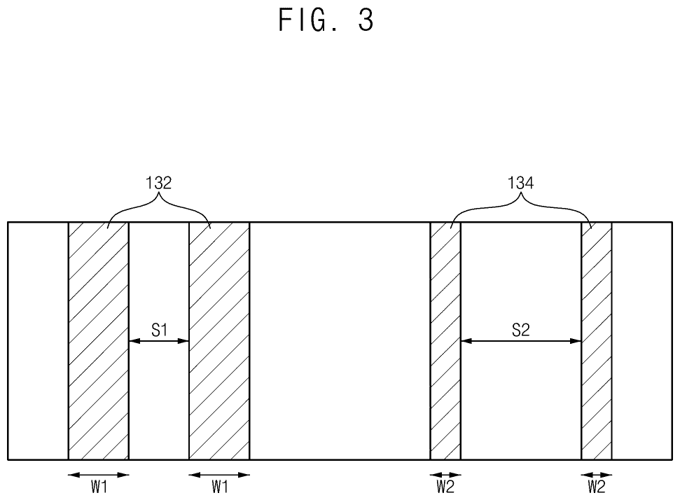

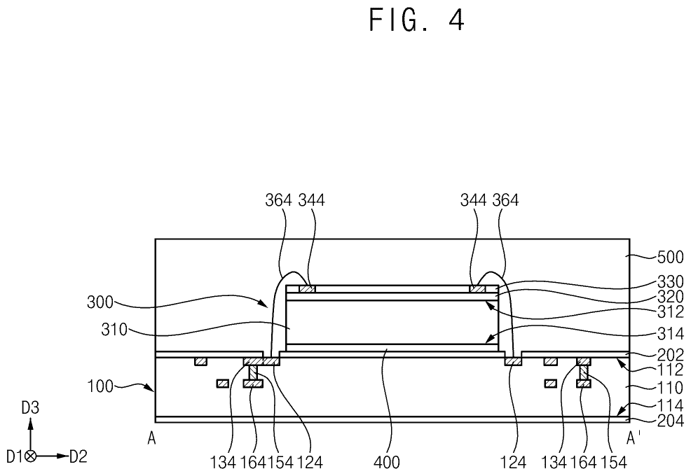

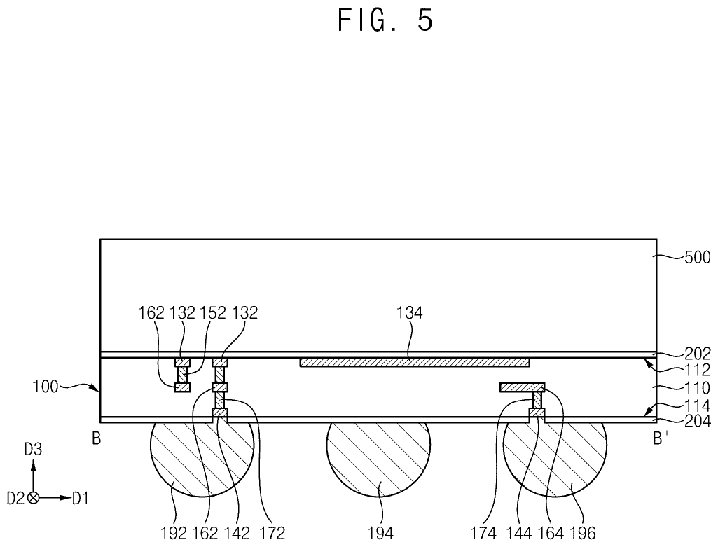

FIG. 1 is a plan view illustrating a semiconductor package in accordance with example embodiments, FIG. 2 is an enlarged plan view of a region X of FIG. 1, FIG. 3 is a plan view illustrating widths of first and second wirings and distances between the first wirings and between the second wirings, FIG. 4 is a cross-sectional view taken along line A-A′ of FIG. 1, and FIG. 5 is a cross-sectional view taken along line B-B′ of FIG. 1.

FIGS. 1 and 2 do not show a molding member and a first substrate protective layer in order to avoid the complexity of drawings.

Referring to FIGS. 1 to 5, the semiconductor package may include a package substrate structure 100, first and second semiconductor chips 300 and 305 and a molding member 500 on the package substrate structure 100.

The semiconductor package may further include first and second bonding wires 362 and 364, an adhesion layer 400, and first to third conductive connection members 192, 194 and 196.

In example embodiments, the semiconductor package may be a multi-chip package (MCP) including a plurality of semiconductor chips, which are the same type as each other or different types from each other. Alternatively, the semiconductor package may be a system in package (SIP) in which various types of semiconductor packages are vertically stacked or horizontally arranged to have an independent function.

In example embodiments, the first and second semiconductor chips 300 and 305 may be the same type of chips having the same structure and size, and may be spaced apart from each other in the first direction D1, however, the inventive concept is not limited thereto. For example, the semiconductor package may include a plurality of first semiconductor chips 300 and a plurality of second semiconductor chips 305 sequentially stacked in the third direction D3, or may include more than two semiconductor chips spaced apart from each other in each of the first and second directions D1 and D2.

The package substrate structure 100 may include a package substrate 110 having first and second surfaces 112 and 114 opposite to each other in the third direction D3, a first substrate protective layer 202 on the first surface 112 of the package substrate 110, and a second substrate protective layer 204 on the second surface 114 of the package substrate 110. Each of the first and second substrate protective layers 202 and 204 may include an insulating material, e.g., an oxide such as silicon oxide or an insulating nitride such as silicon nitride.

The package substrate 110 may be a printed circuit board (PCB). The PCB may be a multi-layered circuit board including various circuit patterns, e.g., transistors, wirings, vias, contact plugs, conductive pads.

In example embodiments, the circuit patterns may include first and second substrate pads 122 and 124 adjacent to the first surface 112 of the package substrate 110, and third and fourth substrate pads 142 and 144 adjacent to the second surface 114 of the package substrate 110. The first and second substrate pads 122 and 124 may be covered by the first substrate protective layer 202 on the first surface 112 of the package substrate 110, and the third and fourth substrate pads 142 and 144 may be covered by the second substrate protective layer 204 on the second surface 114 of the package substrate 110.

Each of the first and second substrate pads 122 and 124 may transfer electrical signals to a semiconductor chip that may be mounted on the package substrate 110, and may serve as a bonding pad such as bonding fingers. Each of the third and fourth substrate pads 142 and 144 may transfer electrical signals to a module substrate disposed under the package substrate 110.

The circuit patterns may further include first to fourth wirings 132, 134, 162 and 164 and first to fourth vias 152, 154, 172 and 174. Each of the first and second wirings 132 and 134 may be disposed at the same level as the first and second substrate pads 122 and 124 in the third direction D3. The first and second vias 152 and 154 may be disposed at the same level as each other in the third direction D3, and may contact lower surfaces of the first and second substrate pads 122 and 124 or the first and second wirings 132 and 134.

The third and fourth wirings 162 and 164 may be disposed at the same level as each other in the third direction D3, and may contact lower surfaces of the first and second vias 152 and 154. The third and fourth vias 172 and 174 may be disposed at the same level as each other in the third direction D3, and may contact lower surfaces of the third and fourth wirings 162 and 164. The third and fourth substrate pads 142 and 144 may contact lower surfaces of the third and fourth vias 172 and 174 in the third direction D3, respectively.

FIGS. 4 and 5 show that the first to fourth substrate pads 122, 124, 142 and 144 and the first to fourth wirings 132, 134, 162 and 164 are disposed at three levels in the third direction D3, however, the inventive concept is not limited thereto, and may be disposed at a single level or a plurality of levels.

The first wiring 132 may contact the first substrate pad 122, and the second wiring 134 may contact the second substrate pad 124. The first wiring 132 may be electrically connected to the third substrate pad 142 through the first via 152, the third wiring 162 and the third via 172, and the second wiring 134 may be electrically connected to the fourth substrate pad 144 through the second via 154, the fourth wiring 164 and the fourth via 174.

In an example embodiment, a first width W1 in the horizontal direction of the first wiring 132 may be equal to or less than a width in the horizontal direction of the first substrate pad 122, and a second width W2 in the horizontal direction of the second wiring 134 may be equal to or less than a width in the horizontal direction of the second substrate pad 124, however, the inventive concept is not limited thereto.

In example embodiments, an extension length in the horizontal direction of the second wiring 134 may be greater than an extension length in the horizontal direction of the first wiring 132, the second width W2 of the second wiring 134 may be greater than the first width W1 of the first wiring 132, and a second distance S2 between the second wirings 134 may be greater than a first distance S1 between the first wirings 132.

A first one of the first wirings 132 may include a first portion extending in the second direction D2, a second portion extending in the fourth direction D4 and connected to the first portion, and a third portion extending in the second direction D2 and connected to the second portion. An extension length of the first one of the first wirings 132 may be a sum of extension lengths of the first to third portions, respectively, in corresponding extension directions. A second one of the first wirings 132 may include a first portion extending in the second direction D2, and a second portion extending in the fourth direction D4 and connected to the first portion. An extension length of the second one of the first wirings 132 may be a sum of extension lengths of the first and second portions, respectively, in corresponding extension directions.

A first one of the second wirings 134 may include a first portion extending in the second direction D2, a second portion extending in the fourth direction D4 and connected to the first portion, and a third portion extending in the first direction D1 and connected to the second portion, and a fourth portion extending in the fourth direction D4 and connected to the third portion. An extension length of the first one of the second wirings 134 may be a sum of extension lengths of the first to fourth portions, respectively, in corresponding extension directions. A second one of the second wirings 134 may include a first portion extending in the second direction D2, a second portion extending in the fourth direction D4 and connected to the first portion, and a third portion extending in the first direction D1 and connected to the second portion. An extension length of the second one of the second wirings 134 may be a sum of extension lengths of the first to third portions, respectively, in corresponding extension directions.

FIGS. 4 and 5 show that the portions of each of the first and second wirings 132 and 134 are disposed at the same level, however, the inventive concept is not limited thereto.

For example, the portions of each of the first and second wirings 132 and 134 may be disposed at a single level, or may be disposed at a plurality of levels and connected to each other by vias. Furthermore, each portion of each of the first and second wirings 132 and 134 may also be disposed at a single level, or may be divided into a plurality of pieces, which may be disposed at a plurality of levels and connected to each other by vias.

If the portions of each of the first and second wirings 132 and 134 are disposed at a plurality of levels, respectively, some of the first to third portions of the first wiring 132 may be disposed not only at a level of the first substrate pad 122, but also at a level of the third wiring 162 or the third substrate pad 142, and may be connected to others of the first to third portions of the first wiring 132 by the first via 152 or the third via 172. Likewise, some of the first to fourth portions of the second wiring 134 may be disposed not only at a level of the second substrate pad 124, but also at a level of the fourth wiring 164 or the fourth substrate pad 144, and may be connected to others of the first to fourth portions of the second wiring 134 by the second via 154 or the fourth via 174.

If the portions of the first wiring 132 are disposed at a plurality of levels and electrically connected to each other by the first via 152 and/or the third via 172, or if the portions of the second wiring 134 are disposed at a plurality of levels and electrically connected to each other by the second via 154 and/or the fourth via 174, the portions of the first wiring 132 and the first via 152 and/or the third via 172 may be collectively referred to as a first wiring structure, and the portions of the second wiring 134 and the second via 154 and/or the fourth via 174 may be collectively referred to as a second wiring structure.

A sum of extension lengths of portions of the second wiring 134, which may be a sum of extension lengths of all portions of the second wiring structure except for the second via 154 and/or the fourth via 174, may be greater than a sum of extension lengths of portions of the first wiring 132, which may be a sum of extension lengths of all portions of the first wiring structure except for the first via 152 and/or the third via 172. The second width W2 of each portion of the second wiring 134 may be greater than the first width W1 of each portion of the first wiring 132.

As the extension length of the second wiring 134 is greater than that of the first wiring 132, signal transmission characteristics, e.g., transmission speed and transmission loss through the second wiring 134 may be deteriorated. However, in example embodiments, the second wiring 134 may have a width smaller than that of the first wiring 132, so that a parasitic capacitance between the second wirings 134 disposed in the vertical direction, that is, in the third direction D3 may be reduced. The distance between the second wirings 134 disposed in the horizontal direction is greater than the distance between the first wirings 132 disposed in the horizontal direction, so that crosstalk between the second wirings 134 may be reduced.

The first conductive connection member 192 may contact a lower surface of the third substrate pad 142 and a lower surface of the second substrate protective layer 204, and the third conductive connection member 196 may contact a lower surface of the fourth substrate pad 144 and a lower surface of the second substrate protective layer 204. In example embodiments, each of the first to third conductive connection members 192, 194 and 196 may include a conductive bump or a conductive ball.

Each of the first to fourth substrate pads 122, 124, 142 and 144, the first to fourth wirings 132, 134, 162 and 164, and the first to fourth vias 152, 154, 172 and 174 may include a metal, e.g., copper, aluminum, nickel, etc., and each of the first to third conductive connection members 192, 194 and 196 may include, e.g., solder that is an alloy of tin, silver, copper, lead, etc.

Each of the first and second semiconductor chips 300 and 305 may include a substrate 310 having first and second surfaces 312 and 314, respectively, opposite to each other in the third direction D3, and a first insulating interlayer and a second insulating interlayer 320 may be sequentially stacked on the first surface 312 of the corresponding substrate 310.

The substrate 310 may include first and second edges E1 and E2 opposite to each other in the second direction D2, and third and fourth edges E3 and E4 opposite to each other in the first direction D1. In example embodiments, the first and second edges E1 and E2 of the substrate 310 may have the same length in the first direction D1, and the third and fourth edges E3 and E4 of the substrate 310 may have the same length in the second direction D2.

The substrate 310 may include, for example, a semiconductor material such as silicon, germanium, or silicon-germanium, or III-V compounds such as GaP, GaAs, GaSb, etc. In an example embodiment, the substrate 310 may be a silicon-on-insulator (SOI) substrate or a germanium-on-insulator (GOI) substrate.

A circuit device, e.g., a logic device or a memory device may be disposed on the first surface 312 of the substrate 310. The memory device may include a volatile memory device such as a DRAM device, an SRAM device, etc., or a non-volatile memory device such as a flash memory device, an EEPROM device, etc. The circuit device may include circuit patterns, which may be covered by the first insulating interlayer.

The second insulating interlayer 320 may include a wiring structure therein. The wiring structure may include, e.g., wirings, vias, contact plugs, etc.

The first insulating interlayer and the second insulating interlayer 320 may include, e.g., an oxide such as silicon oxide, an insulting nitride such as silicon nitride, or a low-k dielectric material. The wirings, the vias, the contact plugs, etc., may include a conductive material, e.g., a metal, a metal nitride, a metal silicide, etc.

First and second chip pads 342 and 344 may be disposed on the second insulating interlayer 320, and may be electrically connected to the wiring structure in the second insulating interlayer 320. Sidewalls of the first and second chip pads 342 and 344 may be covered by a chip protective layer 330 on the second insulating interlayer 320.

In example embodiments, the first and second chip pads 342 and 344 may be spaced apart from each other in the first direction D1 at an area adjacent to each of the first and second edges E1 and E2 to form a chip pad column. In an example embodiment, the chip pad column may include a first chip pad group including eight first chip pads 342 arranged in the first direction D1, and a second chip pad group including eight second chip pads 344 arranged in the first direction D1, and the first and second chip pad groups may be spaced apart from each other in the first direction D1. FIG. 1 shows two first chip pads 342 among the eight first chip pads 342 and two second chip pads 344 among the eight second chip pads 344.

However, the inventive concept is not limited thereto, and for example, the chip pad column may further include a third chip pad group between the first and second chip pad groups, and each of the first to third chip pad groups may include more or less than eight chip pads.

FIG. 1 shows that the chip pad column is disposed at the area adjacent to each of the first and second edges E1 and E2 of each of the first and second semiconductor chips 300 and 305, however, the inventive concept is not limited thereto. For example, the chip pad column may be disposed at an area adjacent to only one of the first and second edges E1 and E2 of each of the first and second semiconductor chips 300 and 305. Alternatively, the chip pad column may be disposed at an area adjacent to each of the first and third edges E1 and E3, or each of the first and fourth edges E1 and E4 so as to be arranged in an “L”shape.

Each of the first and second semiconductor chips 300 and 305 may be bonded to an upper surface of the first substrate protective layer 202 included in the package substrate structure 100 through the adhesion layer 400 on the second surface 314 of the substrate 310, and the first and second chip pads 342 and 344 included in each of the first and second semiconductor chips 300 and 305 may be disposed adjacent to the first and second substrate pads 122 and 124, respectively, included in the package substrate structure 100.

The adhesion layer 400 may include an adhesive material, e.g., die attach film (DAF).

In example embodiments, the first bonding wire 362 may contact the first substrate pad 122 of the package substrate structure 100 and the first chip pad 342 of each of the first and second semiconductor chips 300 and 305, and thus may electrically connect the first substrate pad 122 and the first chip pad 342 to each other. The second bonding wire 364 may contact the second substrate pad 124 of the package substrate structure 100 and the second chip pad 344 of each of the first and second semiconductor chips 300 and 305, and thus may electrically connect the second substrate pad 124 and the second chip pad 344 to each other.

Each of the first and second bonding wires 363 and 364 may include a metal, e.g., copper, aluminum, tungsten, nickel, molybdenum, gold, silver, chromium, tin, titanium, etc.

The molding member 500 may be disposed on the package substrate structure 100, and may cover the first and second semiconductor chips 300 and 305, the adhesion layer 400, and the first and second bonding wires 362 and 364. The molding member 500 may include, e.g., epoxy molding compound (EMC).

The semiconductor package may include a plurality of semiconductor chips, e.g., the first and second semiconductor chips 300 and 305 that may be spaced apart from each other on the package substrate structure 100. The first chip pad 342 of each of the first and second semiconductor chips 300 and 305 and the first wiring 132 electrically connected to the first chip pad 342 through the first bonding wire 362 and the first substrate pad 122 may be electrically connected to the first conductive connection member 192 through, e.g., the first via 152, the third wiring 162 and the third via 172. The second chip pad 344 of each of the first and second semiconductor chips 300 and 305 and the second wiring 134 electrically connected to the second chip pad 344 through the second bonding wire 364 and the second substrate pad 124 may be electrically connected to the third conductive connection member 196 through, e.g., the second via 154, the fourth wiring 164 and the fourth via 174.

A distance in the horizontal direction between the first conductive connection member 192 and the first substrate pad 122 may be different from a distance in the horizontal direction between the third conductive connection member 196 and the second substrate pad 124, and thus the first and second wirings 132 and 134 may have different extension lengths in the horizontal direction.

In example embodiments, each of the second wirings 134 having a relatively long extension length may have a width smaller than that of each of the first wirings 132 having a relatively small extension length, so that a parasitic capacitance between the second wirings 134 may be reduced. Additionally, the distance between the second wirings 134 may be greater than the distance between the first wirings 132, so that crosstalk between the second wirings 134 may be reduced.

Accordingly, even though the first and second wirings 132 and 134 electrically connected to the first and second chip pads 342 and 344, respectively, of each of the first and second semiconductor chips 300 and 305 have the different extension lengths due to the difference between the distance from the first wiring 132 to the first conductive connection member 192 and the distance from the second wiring 134 to the second conductive connection member 194, that is, even though the second wirings 134 have extension lengths greater than those of the first wirings 132, the deterioration of signal transmission characteristics may be compensated by the reduction of the parasitic capacitance and the crosstalk.

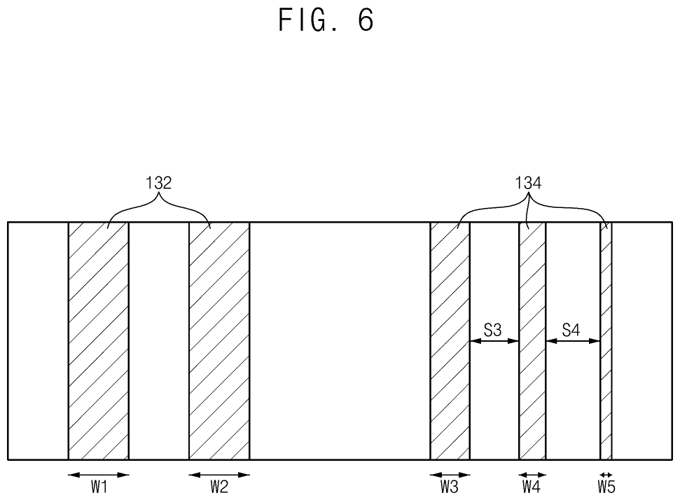

FIG. 6 is a plan view illustrating widths and distances of the first and second wirings, which may correspond to FIG. 3.

Referring to FIG. 6, the second wirings 134 may have third, fourth and fifth widths W3, W4 and W5 in the horizontal direction, which may be smaller than the first width W1.

The second wirings 134 may have different extension lengths from each other, and a width of a first one of the second wirings 134 having a longer extension length may be smaller than that of a second one of the second wirings 134 having a smaller extension length so that the reduction of the parasitic capacitance and the crosstalk may be maximized.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A package substrate structure comprising:
a package substrate having first and second surfaces opposite to each other in a vertical direction;
first and second substrate pads disposed at the same level as each other in the package substrate, the first and second substrate pads being adjacent to the first surface of the package substrate;
a first wiring structure in the package substrate, at least a portion of the first wiring structure being at the same level as the first substrate pad and contacting the first substrate pad; and
a second wiring structure in the package substrate, at least a portion of the second wiring structure being at the same level as the second substrate pad and contacting the second substrate pad, and the second wiring structure having an extension length greater than an extension length of the first wiring structure and a width smaller than a width of the first wiring structure.

2. The package substrate structure according to claim 1, further comprising:
a plurality of first wiring structures spaced apart from each other in a horizontal direction and a plurality of second wiring structures spaced apart from each other in the horizontal direction, the first wiring structure being one of the plurality of first wiring structures, and the second wiring structure being one of the plurality of second wiring structures,
wherein a distance between the second wiring structures is greater than a distance between the first wiring structures.

3. The package substrate structure according to claim 1, further comprising:
a plurality of second wiring structures spaced apart from each other in a horizontal direction, the second wiring structure being one of the plurality of second wiring structures, and the plurality of second wiring structures having extension lengths different from each other,
wherein a first one of the plurality of second wiring structures that has a longer extension length has a width smaller than a width of a second one of the plurality of second wiring structures that has a shorter extension length.

4. The package substrate structure according to claim 1, wherein the second wiring structure includes:
a first portion extending in a first direction;
a second portion extending in a second direction and being connected to the first portion; and
a third portion extending in a third direction and being connected to the second portion.

5. The package substrate structure according to claim 4, wherein the first, second and third portions of the second wiring structure are disposed at the same level.

6. The package substrate structure according to claim 4, wherein at least one of the first, second, and third portions of the second wiring structure is disposed at a level different from levels of remaining ones of the first, second and third portions of the second wiring structure.

7. The package substrate structure according to claim 6, wherein the second wiring structure further includes a via electrically connecting the at least one of the first, second and third portions of the second wiring structure to the remaining ones of the first, second and third portions of the second wiring structure.

8. The package substrate structure according to claim 4, wherein the first and third directions are perpendicular to each other, and the second direction has an acute angle with respect to the first and third directions.

9. The package substrate structure according to claim 1, further comprising third and fourth substrate pads at the same level as each other in the package substrate, the third and fourth substrate pads electrically connected to the first and second wirings, respectively.

10. A semiconductor package comprising:
a package substrate structure including:
a package substrate having first and second surfaces opposite to each other in a vertical direction;
first and second substrate pads disposed at the same level as each other in the package substrate, the first and second substrate pads being adjacent to the first surface of the package substrate;
a first wiring structure in the package substrate, at least a portion of the first wiring structure being at the same level as the first substrate pad and contacting the first substrate pad; and
a second wiring structure in the package substrate, at least a portion of the second wiring structure being at the same level as the second substrate pad and contacting the second substrate pad, and the second wiring structure having an extension length greater than an extension length of the first wiring structure and a width smaller than a width of the first wiring structure;
a first semiconductor chip on the package substrate structure, the first semiconductor chip including first and second chip pads at an upper portion of the first semiconductor chip;
a first bonding wire contacting the first chip pad and the first substrate pad; and
a second bonding wire contacting the second chip pad and the second substrate pad.

11. The semiconductor package according to claim 10, further comprising:
a plurality of first chip pads spaced apart from each other in a horizontal direction parallel to an upper surface of the package substrate, the plurality of first chip pads forming a first chip pad group, and the first chip pad being one of the plurality of first chip pads;
a plurality of first bonding wires, the first bonding wire being one of the plurality of first bonding wires;
a plurality of first substrate pads, the first substrate pad being one of the plurality of first substrate pads;
a plurality of first wiring structures, the first wiring structure being one of the plurality of first wiring structures;
a plurality of second chip pads spaced apart from each other in the horizontal direction, the plurality of second chip pads forming a second chip pad group, and the second chip pad being one of the plurality of second chip pads;
a plurality of second bonding wires, the second bonding wire being one of the plurality of second bonding wires;
a plurality of second substrate pads, the second substrate pad being one of the plurality of second substrate pads; and
a plurality of second wiring structures, the second wiring structure being one of the plurality of second wiring structures,
wherein the first and second chip pad groups are spaced apart from each other in the horizontal direction.

12. The semiconductor package according to claim 11, wherein the first chip pad group includes eight first chip pads, and the second chip pad group includes eight second chip pads.

13. The semiconductor package according to claim 10, further comprising third and fourth substrate pads at the same level as each other in the package substrate, the third and fourth substrate pads electrically connected to the first and second wiring structures, respectively.

14. The semiconductor package according to claim 13, further comprising first and second conductive connection members on a lower surface of the package substrate structure and contacting the third and fourth substrate pads, respectively,
wherein a horizontal distance between the second chip pad and the second conductive connection member is greater than a horizontal distance between the first chip pad and the first conductive connection member.

15. The semiconductor package according to claim 10, further comprising a second semiconductor chip spaced apart from the first semiconductor chip on the package substrate structure in a horizontal direction parallel to an upper surface of the package substrate.

16. The semiconductor package according to claim 10, further comprising:
a plurality of first wiring structures spaced apart from each other in a horizontal direction parallel to an upper surface of the package substrate, the first wiring structure being one of the plurality of first wiring structures; and
a plurality of second wiring structures spaced apart from each other in the horizontal direction, the second wiring structure being one of the plurality of second wiring structures,
wherein a distance between neighboring ones of the plurality of second wiring structures is greater than a distance between neighboring ones of the plurality of first wiring structures.

17. The semiconductor package according to claim 10, further comprising:
a plurality of second wiring structures spaced apart from each other in a horizontal direction parallel to an upper surface of the package substrate, the second wiring structure being one of the plurality of second wiring structures, and the plurality of second wiring structures having extension lengths different from each other,
wherein a first one of the plurality of second wiring structures that has a longer extension length has a width smaller than a width of a second one of the plurality of second wiring structures that has a shorter extension length.

18. A semiconductor package comprising:
a package substrate structure including:
a package substrate having first and second surfaces opposite to each other in a vertical direction;
first and second substrate pads disposed at the same level as each other in the package substrate, the first and second substrate pads being adjacent to the first surface of the package substrate;
a first wiring structure in the package substrate, at least a portion of the first wiring structure being at the same level as the first substrate pad and contacting the first substrate pad;
a second wiring structure in the package substrate, at least a portion of the second wiring structure being at the same level as the second substrate pad and contacting the second substrate pad, and the second wiring structure having an extension length greater than an extension length of the first wiring structure and a width smaller than a width of the first wiring structure; and
third and fourth substrate pads at the same level as each other in the package substrate, the third and fourth substrate pads being adjacent to the second surface of the package substrate, and the third and fourth substrate pads being electrically connected to the first and second wiring structures, respectively;
first and second semiconductor chips spaced apart from each other on the package substrate structure in a first direction parallel to an upper surface of the package substrate, the first and second semiconductor chips including first and second chip pads, respectively, at upper portions of the first and second semiconductor chips;
a first bonding wire contacting the first chip pad and the first substrate pad;
a second bonding wire contacting the second chip pad and the second substrate pad; and
first and second conductive connection members on a lower surface of the package substrate structure and contacting the third and fourth substrate pads, respectively.

19. The semiconductor package according to claim 18, further comprising:
a plurality of first chip pads spaced apart from each other in the first direction, the plurality of first chip pads forming a first chip pad group, and the first chip pad being one of the plurality of first chip pads;
a plurality of first bonding wires, the first bonding wire being one of the plurality of first bonding wires;
a plurality of first substrate pads, the first substrate pad being one of the plurality of first substrate pads;
a plurality of first wiring structures, the first wiring structure being one of the plurality of first wiring structures;
a plurality of second chip pads spaced apart from each other in the first direction, the plurality of second chip pads forming a second chip pad group, and the second chip pad being one of the plurality of second chip pads;
a plurality of second bonding wires, the second bonding wire being one of the plurality of second bonding wires;
a plurality of second substrate pads, the second substrate pad being one of the plurality of second substrate pads; and
a plurality of second wiring structures, the second wiring structure being one of the plurality of second wiring structures,
wherein the first and second chip pad groups are spaced apart from each other in the first direction.

20. The semiconductor package according to claim 19, wherein a horizontal distance between each of the plurality of second chip pads and the second conductive connection member is greater than a horizontal distance between each of the plurality of first chip pads and the first conductive connection member.
